(19) United States
(12) Patent Application Publication
(10) Pub. No.: US 2023/0380254 A1
(43) Pub. Date: Nov. 23, 2023

(54) DONOR SUBSTRATE, AND METHOD FOR MANUFACTURING DISPLAY DEVICE

(71) Applicants: Samsung Display Co., Ltd., Yongin-si (KR); Postech Research and Business Development Foundation, Pohang-si (KR)

(72) Inventors: Sungsoon IM, Yongin-si (KR); Jong Kyu KIM, Pohang-si (KR); Hyeon Woong HWANG, Pohang-si (KR); Jeong Hyeon PARK, Pohang-si (KR); Heemin PARK, Yongin-si (KR); Seungyong SONG, Yongin-si (KR); Duckjung LEE, Yongin-si (KR)

(73) Assignees: Samsung Display Co., Ltd., Yongin-si (KR); Postech Research and Business Development Foundation, Pohang-si (KR)

(21) Appl. No.: 18/191,250

(22) Filed: Mar. 28, 2023

(30) Foreign Application Priority Data
May 17, 2022 (KR) 10-2022-0060123

(51) Int. Cl. H10K 71/80; H10K 71/16

(52) U.S. Cl. CPC H10K 71/80; H10K 71/162

(57) ABSTRACT

A method for manufacturing a display device includes providing a donor substrate including a first base substrate and an organic material layer disposed on the first base substrate, etching the organic material layer to form an etched organic material layer using a laser device, providing a display substrate including a second base substrate and a plurality of first electrodes disposed on the second base substrate, aligning the donor substrate and the display substrate such that the etched organic material layer faces the plurality of first electrodes, and transferring the etched organic material layer to the display substrate using an energy generation device.

### CROSS-REFERENCE TO RELATED APPLICATIONS

This application claims priority to and benefits of Korean Patent Application No. 10-2022-0060123 under 35 U.S.C. § 119, filed on May 17, 2022, in the Korean Intellectual Property Office (KIPO), the entire contents of which are incorporated herein by reference.

### BACKGROUND

### 1. Technical Field

The disclosure herein relates to a donor substrate with improved transfer precision and a method for manufacturing a display device.

### 2. Description of the Related Art

A fine metal mask (FMM) or a laser may be used for a method for forming an organic material layer on a display substrate. A transfer method using a laser may include a laser induced thermal imaging (LITI) method, or a laser induced pattern-wise sublimation (LIPS) method. In the LITI method and the LIPS method, a donor substrate including a light-to-heat conversion layer and a light reflection layer may be used. When the light reflectance of the light reflection layer is higher, transfer may occur only in a specific area. Accordingly, transfer does not readily occur in a display substrate overlapping the light reflection layer. However, since an amount of light is also absorbed in a part overlapping the light reflection layer, transfer may also occur in the part overlapping the light reflection layer.

### SUMMARY

The disclosure provides a donor substrate with improved transfer precision.

The disclosure also provides a method for manufacturing a display device by using a donor substrate with improved transfer precision.

An embodiment of the disclosure provides a method for manufacturing a display device. The method may include providing a donor substrate including a first base substrate and an organic material layer disposed on the first base substrate, etching the organic material layer to form an etched organic material layer using a laser device, providing a display substrate including a second base substrate and a plurality of first electrodes disposed on the second base substrate, aligning the donor substrate and the display substrate such that the etched organic material layer faces the plurality of first electrodes, and transferring the etched organic material layer to the display substrate using an energy generation device.

In an embodiment, the organic material layer may include at least one of a hole control layer, a light-emitting layer, and an electron control layer.

In an embodiment, the first base substrate may include at least one of silicon nitride (Si₃N₄), aluminum nitride (AlN), and silicon carbide (SiC).

In an embodiment, the first base substrate may include a light-to-heat conversion layer.

In an embodiment, the laser device may emit light having a wavelength in an ultraviolet region, and the first base substrate may include at least one of indium-tin oxide (ITO), zinc-tin oxide (ZTO), and fluorinated tin oxide (FTO).

In an embodiment, the laser device may emit light having a wavelength in a visible region, and the first base substrate may include at least one of carbon, silicon, and germanium.

In an embodiment, the laser device may emit light having a wavelength in an infrared region, and the first base substrate may include at least one of glass, aluminum oxide (Al₂O₃), and aluminum oxynitride.

In an embodiment, the laser device may be a vertical-cavity surface-emitting laser.

In an embodiment, the transferring of the etched organic material layer to the display substrate may include moving the donor substrate to contact the display substrate, aligning the energy generation device to face the display substrate with the donor substrate interposed therebetween, and supplying energy by the energy generation device.

In an embodiment, the energy generation device may emit light.

In an embodiment, the energy generation device may provide a heat source.

In an embodiment, an area of a heat source of the energy generation device may be equal to or greater than an area of the donor substrate in a plan view.

In an embodiment, the energy generation device may supply energy toward the first base substrate while moving on the donor substrate.

In an embodiment, the laser device may emit laser toward the organic material layer while moving on the donor substrate.

In an embodiment, the display substrate may further include a hole control layer disposed on the plurality of first electrodes.

In an embodiment, the transferring of the etched organic material layer to the display substrate may include transferring a light-emitting layer on the hole control layer, and transferring the electron control layer on the light-emitting layer.

In an embodiment, the etched organic material layer may include a hole control layer, a light-emitting layer, and an electron control layer, and the transferring of the etched organic material layer to the display substrate may include transferring, all at once, the hole control layer, the light-emitting layer, and the electron control layer, each sequentially stacked, onto each of the plurality of first electrodes.

In an embodiment of the disclosure, a donor substrate may include a base substrate, and an etched pattern disposed on the base substrate, including an organic material, and constituting at least a part of a light-emitting element.

In an embodiment, the base substrate may include at least one of silicon nitride (Si₃N₄), aluminum nitride (AlN), and silicon carbide (SiC).

In an embodiment, the base substrate may include a light-to-heat conversion layer, and the base substrate may include at least one of indium-tin oxide (ITO), zinc-tin oxide (ZTO), and fluorinated tin oxide (FTO).

In an embodiment, the base substrate may include a light-to-heat conversion layer, and the base substrate may include at least one of carbon, silicon, and germanium.

In an embodiment, the base substrate may include a light-to-heat conversion layer, and the base substrate may include at least one of glass, aluminum oxide (Al₂O₃), and aluminum oxynitride.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIG. 2 is a schematic cross-sectional view of a display device according to an embodiment of the disclosure;

FIG. 3A is a schematic cross-sectional view of an initial donor substrate according to an embodiment of the disclosure;

FIG. 3B is a schematic cross-sectional view of an initial donor substrate according to an embodiment of the disclosure;

FIG. 4 is a flowchart of a method for manufacturing a display device according to an embodiment of the disclosure;

FIGS. 5A and 5B are schematic diagrams illustrating a part of a method for manufacturing a display device according to an embodiment of the disclosure;

FIG. 6 is a schematic cross-sectional view illustrating an etched donor substrate according to an embodiment of the disclosure;

FIG. 7A is a schematic diagram illustrating a part of a method for manufacturing a display device according to an embodiment of the disclosure;

FIG. 7B is an enlarged view of a part corresponding to AA′ in FIG. 7A;

FIG. 8 is a schematic diagram illustrating a part of a method for manufacturing a display device according to an embodiment of the disclosure;

FIG. 9 is a schematic diagram illustrating a part of a method for manufacturing a display device according to an embodiment of the disclosure;

FIG. 10A is an enlarged view illustrating a part corresponding to BB′ in FIG. 9 according to an embodiment of the disclosure; and

FIG. 10B is an enlarged view illustrating a part corresponding to BB′ in FIG. 9 according to an embodiment of the disclosure.

### DETAILED DESCRIPTION OF THE EMBODIMENTS

In this specification, when an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the disclosure, a first component may be referred to as a second component, and similarly, a second component may be referred to as a first component. Singular expressions include plural expressions unless the context clearly indicates otherwise.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the drawings.

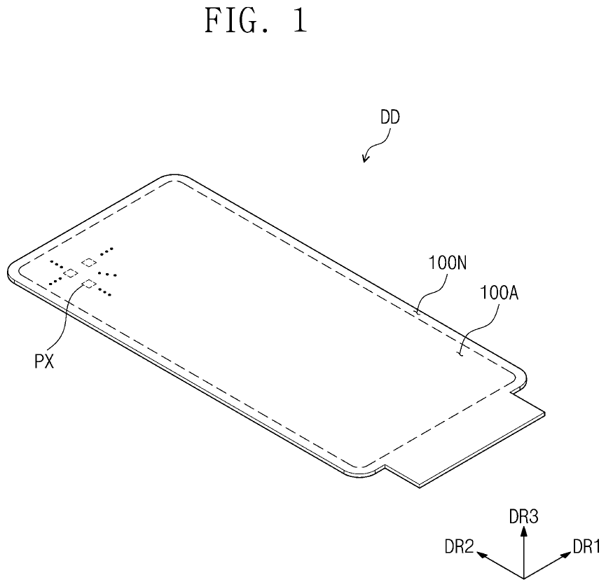

FIG. 1 is a perspective view of a display device DD according to an embodiment of the disclosure.

The display device DD may generate an image, and sense an external input. The display device DD may include a display region 100A and a peripheral region 100N. A pixel PX may be disposed in the display region 100A. The pixel PX may include a first color pixel, a second color pixel, and a third color pixel which generate light having colors different from each other.

The display region 100A may display an image. The display region 100A may include a plane defined by a first direction DR1 and a second direction DR2. The display region 100A may further include curved surfaces respectively bent from at least two sides of the plane. However, the shape of the display region 100A is not limited thereto. For example, the display region 100A may include a plane only, or may include at least two curved surfaces, for example, four curved surfaces respectively bent from four sides of the plane.

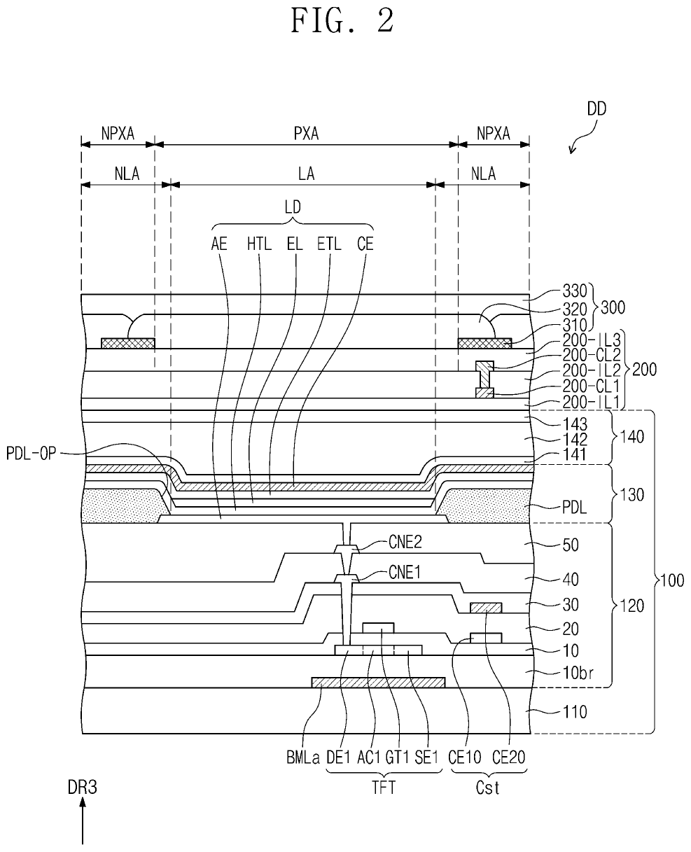

FIG. 2 is a schematic cross-sectional view of a display device DD according to an embodiment of the disclosure. FIG. 2 illustrates a cross-section corresponding to one light-emitting region LA and a non-light-emitting region NLA therearound. FIG. 2 illustrates a light-emitting element LD and a transistor TFT connected thereto. The transistor TFT may be one of multiple transistors included in a driving circuit of a pixel PX. In the embodiment, the transistor TFT is described as a silicon transistor, but may be a metal oxide transistor.

Referring to FIG. 2, the display device DD may include a display panel 100, an input sensor 200, and an anti-reflective member (anti-reflector) 300.

The display panel 100 may be a light-emitting display panel, and, for example, the display panel 100 may be an organic light-emitting display panel, an inorganic light-emitting display panel, a micro-LED display panel, or a nano-LED display panel.

The display panel 100 may include a base layer 110, a circuit layer 120, a light-emitting element layer 130, and an encapsulation layer 140.

The base layer 110 may provide a base surface on which the circuit layer 120 is disposed. The base layer 110 may be a rigid substrate, or a flexible substrate which is bendable, foldable, or rollable. The base layer 110 may be a glass substrate, a metal substrate, or a polymer substrate, but an embodiment of the disclosure is not limited thereto. The base layer 110 may include an inorganic layer, an organic layer, or a composite material layer.

The base layer 110 may have a multi-layered structure. For example, the base layer 110 may include a first synthetic resin layer, a single- or multi-layered inorganic layer, and a second synthetic resin layer disposed on the single- or multi-layered inorganic layer. The first and second synthetic resin layers may each include a polyimide-based resin, but the disclosure is not specially limited.

The circuit layer 120 may be disposed on the base layer 110. The circuit layer 120 may include an insulating layer, a semiconductor pattern, a conductive pattern, a signal line, etc. The circuit layer 120 may include a driving circuit of a pixel PX described in FIG. 1.

A buffer layer 10br may be disposed on the base layer 110. The buffer layer 10br may prevent metal atoms or impurities from diffusing from the base layer 110 to a semiconductor pattern thereabove. The semiconductor pattern may include an active region AC1 of the transistor TFT.

A rear surface metal layer BMLa may be disposed under the transistor TFT. The rear surface metal layer BMLa may block external light reaching to the transistor TFT. The rear surface metal layer BMLa may be disposed between the base layer 110 and the buffer layer 10br. In an embodiment of the disclosure, although not illustrated in FIG. 2, an inorganic barrier layer may be further disposed between the rear surface metal layer BMLa and the buffer layer 10br. The rear surface metal layer BMLa may be connected to an electrode or a line, and may receive a constant voltage or a signal therefrom.

The semiconductor pattern may be disposed on the buffer layer 10br. The semiconductor pattern may include a silicon semiconductor. For example, the silicon semiconductor may include amorphous silicon, polycrystalline silicon, or the like. For example, the semiconductor pattern may include low-temperature polysilicon.

The semiconductor pattern may include a first region having a high conductivity, and a second region having a low conductivity. The first region may be doped with an N-type dopant or a P-type dopant. A P-type transistor may include a region doped with a P-type dopant, and an N-type transistor may include a region doped with an N-type dopant. The second region may be an undoped region, or a region more lightly doped than the first region

The first region may have a higher conductivity than the second region, and may substantially serve as an electrode or a signal line. The second region may substantially correspond to an active region (or channel) of a transistor. In other words, a part of the semiconductor pattern may be the active region of a transistor, and another part may be a source or a drain of the transistor, and still another part may be a connection electrode or a connection signal line.

A source region SE1 (or source), an active region AC1 (or channel), and a drain region DE1 (or drain) of the transistor TFT may be formed in the semiconductor pattern. In a cross-sectional view, the source region SE1 and the drain region DE1 may extend from the active region AC1 in directions opposite to each other.

A first insulating layer 10 may be disposed on the buffer layer 10br. The first insulating layer 10 may overlap multiple pixels PX (see FIG. 1) in common, and cover the semiconductor pattern. The first insulating layer 10 may include an inorganic layer and/or an organic layer, and have a single- or multi-layered structure. The inorganic layer may include at least one of aluminum oxide, titanium oxide, silicon oxide, silicon nitride, silicon oxynitride, zirconium oxide, or hafnium oxide. In the embodiment, the first insulating layer 10 may be a single-layered silicon oxide layer. Not only the first insulating layer 10, but also an insulating layer of the circuit layer 120 to be described later may be an inorganic layer and/or an organic layer, and have a single- or multi-layered structure. The inorganic layer may include at least one of the materials described above, but an embodiment of the disclosure is not limited thereto.

A gate GT1 of the transistor TFT may be disposed on the first insulating layer 10. The gate GT1 may be a part of a metal pattern. The gate GT1 may overlap the active region AC1 in a thickness direction of the base layer 110 (or a third direction DR3). In a process of doping the semiconductor pattern, the gate GT1 may function as a mask. The gate GT1 may include titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium-tin oxide (ITO), indium-zinc oxide (IZO), or the like, but an embodiment of the disclosure is not limited thereto.

A second insulating layer 20 may be disposed on the first insulating layer 10 and cover the gate GT1. A third insulating layer 30 may be disposed on the second insulating layer 20. A second electrode CE20 of a storage capacitor Cst may be disposed between the second insulating layer 20 and the third insulating layer 30. A first electrode CE10 of the storage capacitor Cst may be disposed between the first insulating layer 10 and the second insulating layer 20.

A first connection electrode CNE1 may be disposed on the third insulating layer 30. The first connection electrode CNE1 may be connected to the drain region DE1 of the transistor TFT through a contact hole penetrating the first to third insulating layers 10, 20, and 30.

A fourth insulating layer 40 may be disposed on the third insulating layer 30. A second connection electrode CNE2 may be disposed on the fourth insulating layer 40. The second connection electrode CNE2 may be connected to the first connection electrode CNE1 through a contact hole penetrating the fourth insulating layer 40. A fifth insulating layer 50 may be disposed on the fourth insulating layer 40 and cover the second connection electrode CNE2. A stack structure of the first insulating layer 10 to the fifth insulating layer 50 is illustrated only as an example, and an additional conductive layer and insulating layer may be further disposed.

Each of the fourth insulating layer 40 and the fifth insulating layer 50 may be an organic layer. For example, the organic layer may include a general-purpose polymer such as benzocyclobutene (BCB), polyimide, hexamethyldisiloxane (HMDSO), polymethylmethacrylate (PMMA), or polystyrene (PS), a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, a blend thereof, and etc.

The light-emitting element layer 130 may be disposed on the circuit layer 120. The light-emitting element layer 130 may include a light-emitting element of the pixel PX described in FIG. 1. For example, the light-emitting element may include an organic light-emitting material, an inorganic light-emitting material, an organic-inorganic light-emitting material, a quantum dot, a quantum rod, a micro-LED, or a nano-LED.

The light-emitting element LD may include a first electrode AE (or pixel electrode), a hole control layer HTL, a light-emitting layer EL, an electron control layer ETL, and a second electrode CE (or common electrode). The first electrode AE may be disposed on the fifth insulating layer 50. The first electrode AE may be a translucent electrode, a transparent electrode, or a reflective electrode. The first electrode AE may include a reflective layer formed of Ag, Mg, Al, Pt, Pd, Au, Ni, Nd, Jr, Cr, or a compound thereof, and a transparent or translucent electrode layer formed on the reflective layer. The transparent or translucent electrode layer may include at least one selected from the group consisting of indium-tin oxide (ITO), indium-zinc oxide (IZO), indium-gallium-zinc oxide (IGZO), zinc oxide (ZnO), indium oxide (In₂O₃), and aluminum-doped zinc oxide (AZO). For example, the first electrode AE may include a stack structure of ITO/Ag/ITO.

A pixel-defining film PDL may be disposed on the fifth insulating layer 50. According to an embodiment, the pixel-defining film PDL may have a light-absorbing property, and thus may have, for example, a black color. The pixel-defining film PDL may include a black coloring agent. The black coloring agent may include a black dye or a black pigment. The black coloring agent may include carbon black, a metal such as chromium, or an oxide thereof. The pixel-defining film PDL may correspond to a light-blocking pattern having light-blocking characteristics.

The pixel-defining film PDL may partially cover the first electrode AE. For example, an opening PDL-OP partially exposing the first electrode AE may be defined in the pixel-defining film PDL. The opening PDL-OP of the pixel-defining film PDL may define the light-emitting region LA.

The hole control layer HTL may be disposed on the first electrode AE and the pixel-defining film PDL. The hole control layer HTL may have a single layer composed of a single material, a single layer composed of multiple different materials, or a multi-layered structure having multiple layers composed of multiple different materials. For example, the hole control layer HTL may have a single-layered structure of a hole injection layer or a hole transport layer, or a single-layered structure composed of a hole injection material or a hole transport material. In an embodiment, the hole control layer HTL may include a hole transport layer, and further include a hole injection layer.

The light-emitting layer EL may be disposed on the hole control layer HTL. The light-emitting layer EL may include an organic material and/or an inorganic material. The light-emitting layer EL may generate colored light. The light-emitting layer EL may include an organic light-emitting material or a quantum dot material.

The electron control layer ETL may be disposed on the light-emitting layer EL and the hole control layer HTL. The electron control layer ETL may have a single layer composed of a single material, a single layer composed of multiple different materials, or a multi-layered structure having multiple layers composed of multiple different materials. For example, the electron control layer ETL may have a single-layered structure of an electron injection layer or an electron transport layer, or a single-layered structure composed of an electron injection material or an electron transport material. The electron control layer ETL may have a single-layered structure composed of multiple different materials, or include multiple layers sequentially stacked from the light-emitting layer. In an embodiment, the electron control layer ETL may include an electron transport layer and may further include an electron injection layer.

The encapsulation layer 140 may be disposed on the light-emitting element layer 130. The encapsulation layer 140 may protect the light-emitting element layer 130 from moisture, oxygen, and foreign matters such as dust particles. The encapsulation layer 140 may include an inorganic layer 141, an organic layer 142, and an inorganic layer 143 sequentially stacked, but layers constituting the encapsulation layer 140 are not limited thereto.

The inorganic layers 141 and 143 may protect the light-emitting element layer 130 from moisture and oxygen, and the organic layer 142 may protect the light-emitting element layer 130 from foreign matters such as dust particles. The inorganic layers 141 and 143 may each include a silicon nitride layer, a silicon oxynitride layer, a silicon oxide layer, a titanium oxide layer, an aluminum oxide layer, or the like. The organic layer 142 may include an acryl-based organic layer, but an embodiment of the disclosure is not limited thereto.

An input sensor 200 may be disposed on the display panel 100. The input sensor 200 may sense an external input applied from the outside. The external input may be a user's input. The user's input may include various forms of external inputs such as a part of a user's body, light, heat, a pen, or pressure.

The input sensor 200 may be formed on the display panel 100 through a continuous process. The input sensor 200 may be directly disposed on the display panel 100. In the specification, the phrase “component B is directly disposed on component A” may mean that a third component is not disposed between the component A and the component B. For example, an adhesive layer may not be disposed between the display panel 100 and the input sensor 200.

The anti-reflective member 300 may be disposed on the input sensor 200. The anti-reflective member 300 may reduce the reflection of external light. The anti-reflective member 300 may be directly disposed on the input sensor 200 through a continuous process. The anti-reflective member 300 may include a light-blocking pattern 310, a color filter 320, and a planarization layer 330.

As long as absorbing light, a material constituting the light-blocking pattern 310 is not specially limited. Since the light-blocking pattern 310 is a layer having a black color, the light-blocking pattern 310 according to an embodiment may include a black coloring agent. The black coloring agent may include a black dye or a black pigment. The black coloring agent may include carbon black, metal such as chromium, or an oxide thereof. The light-blocking pattern 310 may prevent external light from being reflected by first conductive patterns 200-CL1 and second conductive patterns 200-CL2.

The color filter 320 may overlap at least a pixel region PXA in the third direction DR3. The color filter 320 may also overlap a non-pixel region NPXA. A part of the color filter 320 may be disposed on the light-blocking pattern 310. The color filter 320 may pass light generated in the light-emitting element LD, and block external light having a specific wavelength range. Accordingly, the color filter 320 may reduce reflection of external light by the first electrode AE or the second electrode CE. The color filter 320 may include a first color filter, a second color filter, and a third color filter respectively corresponding to a first color pixel, a second color pixel, and a third color pixel.

The planarization layer 330 may cover the light-blocking pattern 310 and the color filter 320. The planarization layer 330 may include an organic material and provide a flat upper surface.

The anti-reflective member 300 may lower the reflection of light incident from the outside. The anti-reflective member 300 may include a phase retarder and/or a polarizer. The anti-reflective member 300 may include at least a polarization film.

Although not shown in FIG. 2, the display device DD may include a window (not shown). The window (not shown) may be disposed on the anti-reflective member 300.

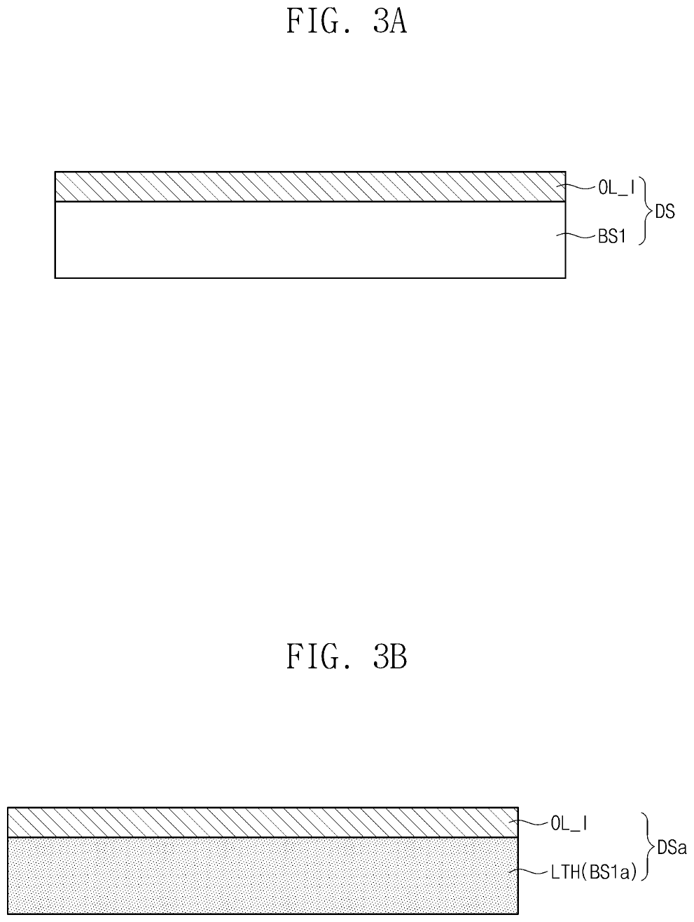

FIG. 3A is a schematic cross-sectional view of an initial donor substrate DS according to an embodiment of the disclosure, and FIG. 3B is a schematic cross-sectional view of an initial donor substrate DSa according to an embodiment of the disclosure.

Referring to FIG. 3A, the initial donor substrate DS may include a first base substrate BS1 and an organic material layer OL_I. The initial donor substrate DS in FIG. 3A may be used in an etching process in which the organic material layer OL_I is evaporated by absorbing light having a specific wavelength.

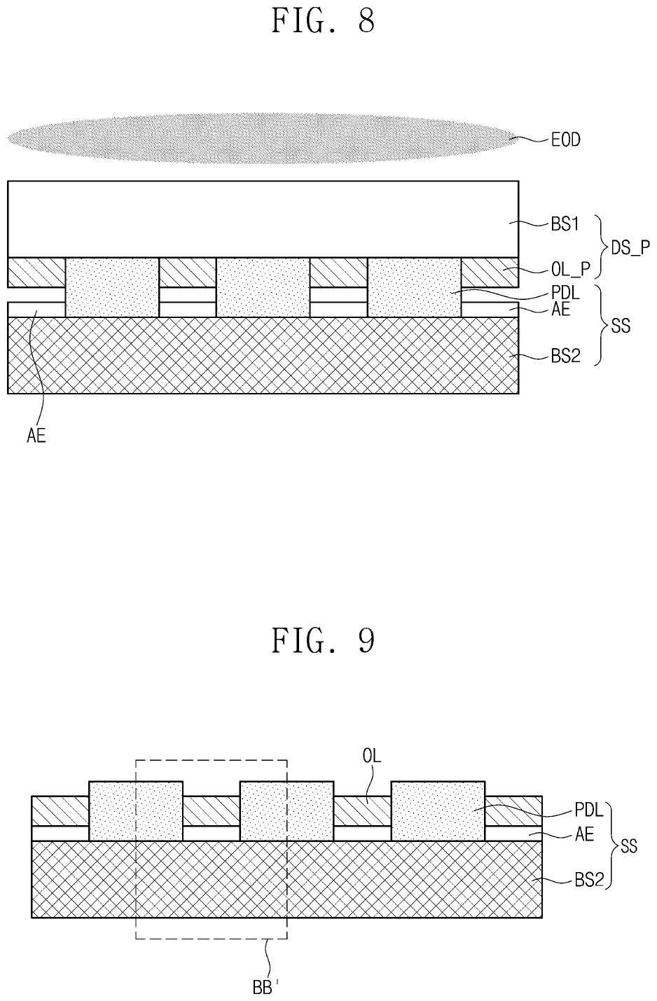

The first base substrate BS1 may support the organic material layer OL_I. The first base substrate BS1 may receive energy from an energy generation device EOD (see FIG. 8) and may include a material having a high thermal conductivity and a small thermal deformation. For example, the first base substrate BS1 may include at least one of silicon nitride (Si₃N₄), aluminum nitride (AlN), and silicon carbide (SiC). The organic material layer OL_I may include an organic material.

Referring to FIG. 3B, the initial donor substrate DSa may include a first base substrate BS1a and the organic material layer OL_I.

The first base substrate BS1a may include a light-to-heat conversion layer LTH. The first base substrate BS1a may include a structure which is capable of not only supporting the organic material layer OL_I, but also absorbing light having a specific wavelength and utilizing heat generated during absorption. The organic material layer OL_I may have a high transmittance or a low absorbance for light having a specific wavelength. In case that light having a specific wavelength is supplied toward the organic material layer OL_I, the light may pass through the organic material layer OL_I having a high transmittance for the corresponding wavelength, and the first base substrate BS1 may absorb light having the specific wavelength. Thereafter, the organic material layer OL_I may be etched using heat generated during absorption.

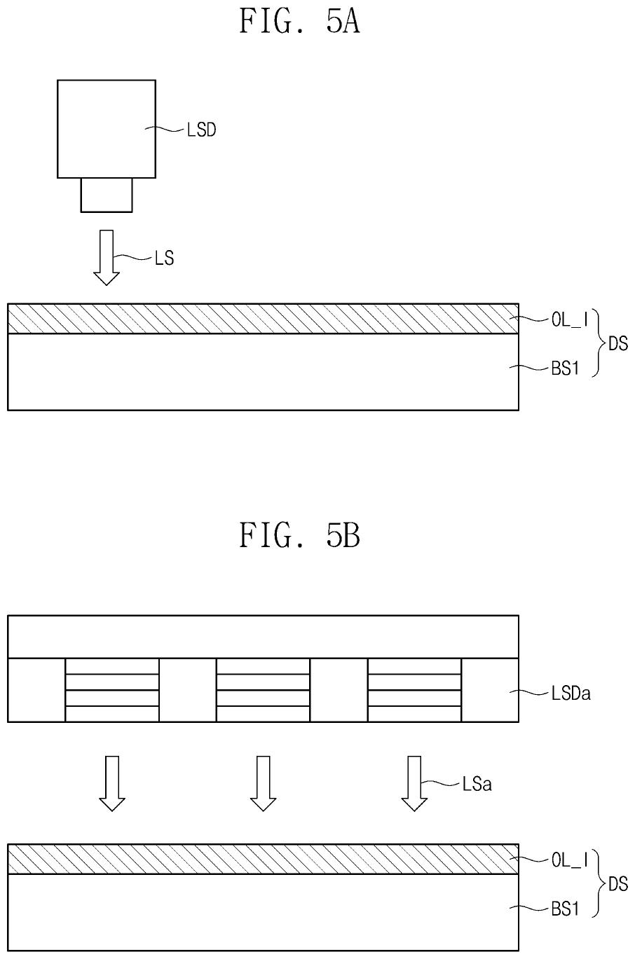

The first base substrate BS1a may receive energy from the energy generation device EOD (see FIG. 8) and may include a material having a high thermal conductivity and a low thermal deformation. A material included in the first base substrate BS1a may be determined depending on a wavelength band of light incident from a laser device LSD or LSDa (see FIG. 5A or FIG. 5B).

For example, the laser device LSD or LSDa (see FIG. 5A or FIG. 5B) may emit light having a wavelength in an ultraviolet range. The first base substrate BS1a (or the light-to-heat conversion layer) may include at least one of indium-tin oxide (ITO), zinc-tin oxide (ZTO), and fluorinated tin oxide (FTO), but an embodiment of the disclosure is not limited thereto.

For example, the laser device LSD or LSDa (see FIG. 5A or FIG. 5B) may emit light having a wavelength in a visible range. The first base substrate BS1a (or the light-to-heat conversion layer) may include at least one of carbon, silicon, and germanium, but an embodiment of the disclosure is not limited thereto.

For example, the laser device LSD or LSDa (see FIG. 5A or FIG. 5B) may emit light having a wavelength in an infrared range. The first base substrate BS1a (or the light-to-heat conversion layer) may include at least one of glass, aluminum oxide (Al₂O₃), and aluminum oxynitride, but an embodiment of the disclosure is not limited thereto.

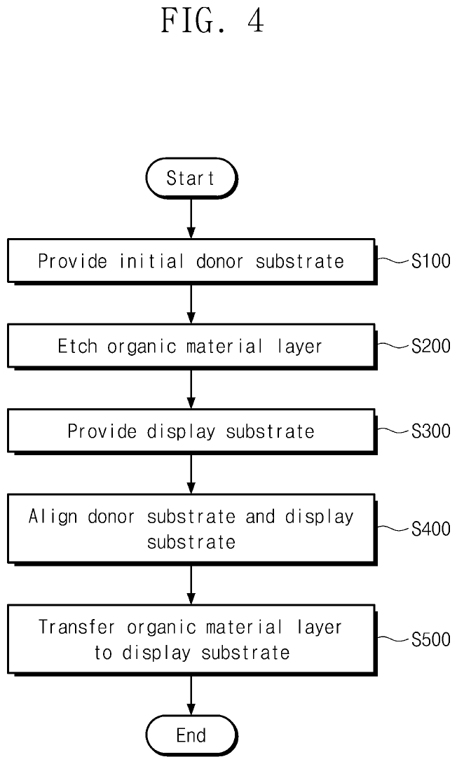

FIG. 4 is a flowchart of a method for manufacturing a display device according to an embodiment of the disclosure. FIGS. 5A and 5B are schematic diagrams illustrating a part of a method for manufacturing a display device according to an embodiment of the disclosure.

Referring to FIGS. 3A, 3B, and 4, an initial donor substrate DS or DSa may be provided (S100). The initial donor substrate DS or DSa may include a first base substrate BS1 or BS1a, and an organic material layer OL_I disposed on the first base substrate BS1 or BS1a.

Referring to FIGS. 4, 5A and 5B, the organic material layer OL_I may be etched using a laser device LSD or LSDa (S200). The organic material layer OL_I may include at least one of a hole injection layer (not shown), a hole transport layer (not shown), a light-emitting layer (see FIG. 2), an electron transport layer (not shown), and an electron injection layer (not shown). For example, the organic material layer OL_I may be a single layer among the hole injection layer (not shown), the hole transport layer (not shown), the light-emitting layer EL, the electron transport layer (not shown), and the electron injection layer (not shown), or may have a multi-layered structure having two or more layers thereamong.

The laser device LSD or LSDa may emit laser LS or LSa toward the organic material layer OL_I. The laser device LSD or LSDa may have a resolution equal to or greater than a pixel PX unit to facilitate a pixel PX (see FIG. 1) pattern formation. The laser device LSD or LSDa may emit light having a wavelength of about 200 nm to about 20000 nm. For example, the laser device LSD or LSDa may emit light having a wavelength in an ultraviolet range. The laser device LSD or LSDa may emit light having a wavelength of about 200 nm to about 350 nm. The laser device LSD or LSDa may emit light having a wavelength in a visible region. The laser device LSD or LSDa may emit light having a wavelength of about 350 nm to about 800 nm. The laser device LSD or LSDa may emit light having a wavelength in an infrared region. The laser device LSD or LSDa may emit light having a wavelength of about 800 nm to about 20000 nm.

Referring to FIG. 5A, while moving on the initial donor substrate DS, the laser device LSD may emit the laser LS toward the organic material layer OL_I.

Referring to FIG. 5B, the laser device LSDa may be a vertical-cavity surface-emitting laser. The laser device LSDa may be laser equipment designed to emit the laser LSa according to an interval of a pixel PX (see FIG. 1). For example, the laser device LSDa may simultaneously emit the laser LSa with an interval corresponding to the size of the pixel PX. The interval may be changed depending on the purpose of the organic material layer OL_I. For example, in case that the organic material layer OL_I is used as a backlight light-emitting element, the interval may have size of one pixel PX; and in case that light-emitting layers use different organic materials and exhibit a red color, a green color, and a blue color respectively, the interval may have a size of each of three pixels PX.

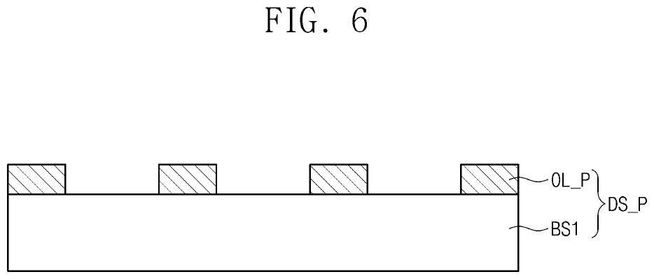

FIG. 6 is a schematic cross-sectional view schematically illustrating an etched donor substrate DS_P according to an embodiment of the disclosure.

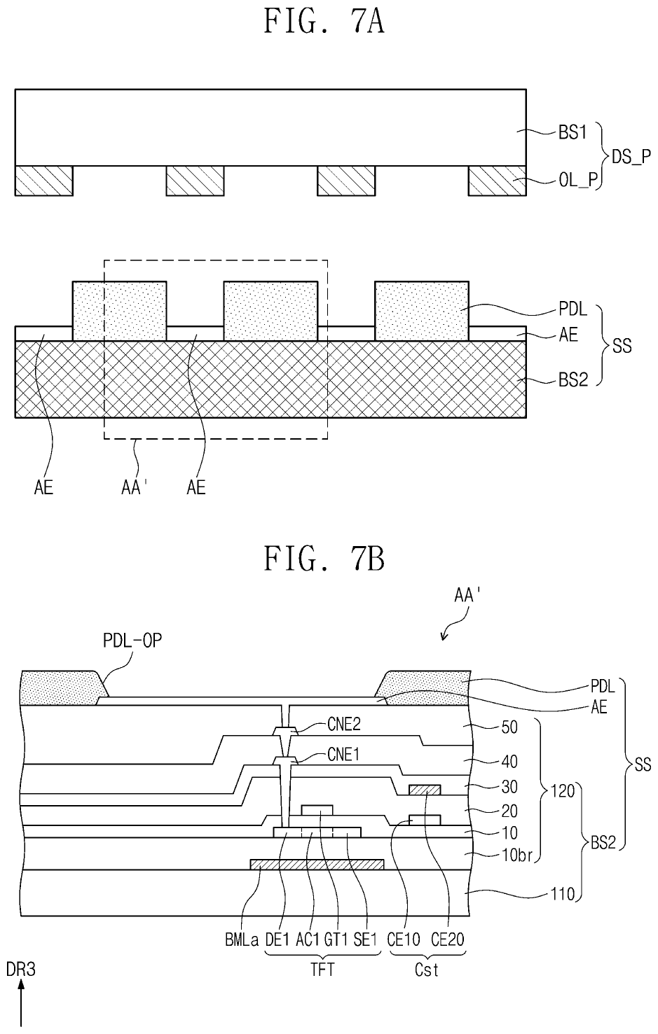

Referring to FIG. 6, the etched donor substrate DS_P may include a first base substrate BS1 and an etched pattern OL_P (or etched organic material layer) including an organic material. The etched pattern OL_P may be disposed on the first base substrate BS1. The etched pattern OL_P may correspond to a part deposited onto a display substrate SS (see FIG. 7A).

The etched pattern OL_P may be a pattern constituting at least a part of a light-emitting element LD (see FIG. 2). For example, the etched pattern OL_P may include a hole control layer HTL (see FIG. 2), a light-emitting layer EL (see FIG. 2), or an electron control layer ETL (see FIG. 2), may include the hole control layer HTL, the light-emitting layer EL, and the electron control layer ETL, may include the hole control layer HTL and the light-emitting layer EL, or may include the light-emitting layer EL and the electron control layer ETL.

FIG. 7A is a schematic diagram illustrating a part of a method for manufacturing a display device according to an embodiment of the disclosure. FIG. 7B is an enlarged view of a part corresponding to AA′ in FIG. 7A.

Referring to FIGS. 4, 7A and 7B, a display substrate SS may be provided (S300). The display substrate SS may include a second base substrate BS2 and multiple first electrodes AE disposed on the second base substrate BS2. The display substrate SS may also include a pixel-defining film PDL disposed on the second base substrate BS2. The etched donor substrate DS_P and the display substrate SS may be aligned (S400) such that the etched organic material layer OL_P faces the first electrodes AE. An organic material of the etched organic material layer OL_P may be aligned to be transferred on the first electrodes AE.

The second base substrate BS2 may include a base layer 110 and a circuit layer 120 (see FIG. 2). The display substrate SS may include the second base substrate BS2, the first electrodes AE, and the pixel-defining film PDL. The etched organic material layer OL_P may be aligned to face the opening PDL-OP (see FIG. 2) defined by the pixel-defining film PDL, and the etched organic material layer OL_P may be transferred onto the first electrodes AE.

The etched pattern OL_P may be a pattern constituting at least a part of the light-emitting element LD (see FIG. 2). For example, the etched pattern OL_P may include a hole control layer HTL (see FIG. 2), a light-emitting layer EL (see FIG. 2), or an electron control layer ETL (see FIG. 2), may include the hole control layer HTL, the light-emitting layer EL, and the electron control layer ETL, may include the hole control layer HTL and the light-emitting layer EL, or may include the light-emitting layer EL and the electron control layer ETL.

FIG. 8 is a schematic diagram illustrating a part of a method for manufacturing a display device according to an embodiment of the disclosure.

Referring to FIGS. 4 and 8, the etched organic material layer OL_P may be transferred to the display substrate SS using an energy generation device EOD (S500). In detail, the etched donor substrate DS_P may be moved to contact the display substrate SS. The pixel-defining film PDL of the display substrate SS and a part of the first base substrate BS1 of the etched donor substrate DS_P may contact each other.

The energy generation device EOD may be aligned to face the display substrate SS with the etched donor substrate DS_P interposed therebetween (or disposed between the energy generation device EOD and the display substrate SS). For example, the energy generation device EOD may be aligned to face the donor substrate DS_P. The energy generation device EOD may supply energy with which the etched organic material layer OL_P may be transferred. The area of the energy generation device EOD may be equal to or larger than the area of the etched donor substrate DS_P. However, the area of the energy generation device EOD is not limited thereto, and may be smaller than the area of the etched donor substrate DS_P. While moving on the etched donor substrate DS_P, the energy generation device EOD may supply energy toward the first base substrate BS1.

The energy generation device EOD may emit light. For example, the energy supplied by the energy generation device EOD may be light.

In another embodiment of the disclosure, the energy generation device EOD may supply heat. For example, the energy generation device EOD may provide a heat source. For example, the energy generation device EOD may be a large-area heat source, and the energy supplied by the energy generation device EOD may be heat. The temperature of the heat may be a sufficiently high temperature at which an organic material may be evaporated, and may be in a temperature range in which thermal deformation of the donor substrate DS_P and the display substrate SS except the etched organic material layer OL_P do not occur.

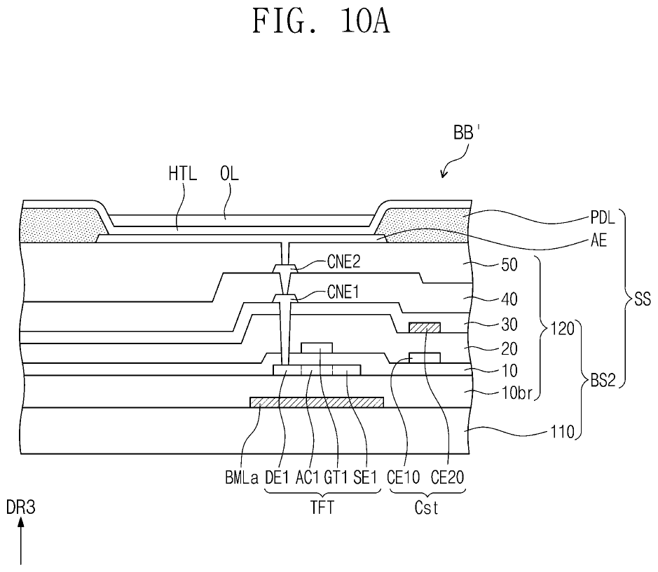

FIG. 9 is a schematic diagram illustrating a part of a method for manufacturing a display device according to an embodiment of the disclosure.

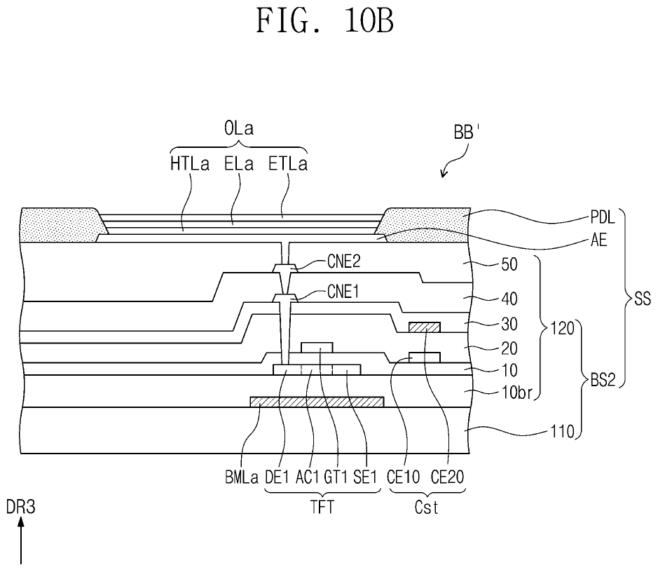

Referring to FIG. 9, the etched organic material layer OL_P (see FIG. 8) may be transferred (or deposited) onto the first electrodes AE of the display substrate SS. The organic layers OL may be formed (or transferred) from the etched organic material layer OL_P transferred on the first electrodes AE. That is, the organic layers OL may be formed on the first electrodes AE of the display substrate SS. The organic layers OL may be a hole control layer HTL or HTLa (see FIG. 10A or FIG. 10B). FIG. 9 illustrates that the organic layers OL are formed (or transferred) on the first electrodes AE, but an embodiment of the disclosure is not limited thereto, and the organic layers OL may be formed (or transferred) on the first electrodes AE and the pixel-defining film PDL.

FIG. 10A is an enlarged view illustrating a part corresponding to BB′ in FIG. 9 according to an embodiment of the disclosure.

Referring to FIGS. 9 and 10A, the etched organic material layer OL_P (see FIG. 8) may be transferred (or deposited) onto the hole control layer HTL. The organic layer OL may be formed from the etched organic material layer OL_P transferred on the hole control layer HTL using the method for manufacturing a display device. That is, the organic layer OL may be formed on the hole control layer HTL of the display substrate SS. The organic layer OL may include the light-emitting layer EL (see FIG. 2), the electron control layer ETL (see FIG. 2), or the light-emitting layer EL and the electron control layer ETL.

In case that the organic layer OL includes the light-emitting layer EL (see FIG. 2) or the electron control layer ETL (see FIG. 2), the light-emitting layer EL and the electron control layer ETL may be sequentially formed. For example, the light-emitting layer EL may be formed (or transferred) on the hole control layer HTL, and the electron control layer ETL may be formed (or transferred) on the light-emitting layer EL.

In an embodiment, in case that the organic layer OL includes both the light-emitting layer EL and the electron control layer ETL, the light-emitting layer EL and the electron control layer ETL may be formed (or transferred) on the hole control layer HTL in a same deposition process.

FIG. 10B is an enlarged view illustrating a part corresponding to BB′ in FIG. 9 according to an embodiment of the disclosure.

Referring to FIG. 10B, an organic material layer OLa transferred onto the display substrate SS may include a hole control layer HTLa, a light-emitting layer ELa, and an electron control layer ETLa. FIG. 10B illustrates a state in which the hole control layer HTLa, the light-emitting layer ELa, and the electron control layer ETLa are transferred in a same deposition process (or all at once). Respective layers of the organic material layer OLa transferred in a same deposition process may have a shape in which edges thereof are continuous.

According to the embodiment of the disclosure, an organic material layer OL of a light-emitting element may be selectively deposited on a pixel unit in a large scale without a mask device. Unlike a typical technology in which a part irradiated with a laser device LS (see FIG. 5A) is transferred, a part remaining after being etched with the laser device LS may be transferred, thereby improving the accuracy of transfer process. Accordingly, it is possible to reduce or remove stitching mura caused by non-uniform transfer of a laser-irradiated region, and an edge defect caused by a blurred boundary between a region irradiated with the laser and a region not irradiated with the laser. The organic material layer OL_P patterned on the donor substrate DS_P may be transferred all at once, thereby reducing a process time and improving accuracy.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A method for manufacturing a display device, comprising:
providing a donor substrate including a first base substrate and an organic material layer disposed on the first base substrate;
etching the organic material layer to form an etched organic material layer using a laser device;
providing a display substrate including a second base substrate and a plurality of first electrodes disposed on the second base substrate;
aligning the donor substrate and the display substrate such that the etched organic material layer faces the plurality of first electrodes; and
transferring the etched organic material layer to the display substrate using an energy generation device.

2. The method of claim 1, wherein the organic material layer comprises at least one of a hole control layer, a light-emitting layer, and an electron control layer.

3. The method of claim 1, wherein the first base substrate comprises at least one of silicon nitride (Si₃N₄), aluminum nitride (AlN), and silicon carbide (SiC).

4. The method of claim 1, wherein the first base substrate comprises a light-to-heat conversion layer.

5. The method of claim 4, wherein
the laser device emits light having a wavelength in an ultraviolet region, and
the first base substrate comprises at least one of indium-tin oxide (ITO), zinc-tin oxide (ZTO), and fluorinated tin oxide (FTO).

6. The method of claim 4, wherein
the laser device emits light having a wavelength in a visible region, and
the first base substrate comprises at least one of carbon, silicon, and germanium.

7. The method of claim 4, wherein
the laser device emits light having a wavelength in an infrared region, and
the first base substrate comprises at least one of glass, aluminum oxide (Al₂O₃), and aluminum oxynitride.

8. The method of claim 1, wherein the laser device is a vertical-cavity surface-emitting laser.

9. The method of claim 1, wherein the transferring of the etched organic material layer to the display substrate comprises:
moving the donor substrate to contact the display substrate;
aligning the energy generation device to face the display substrate with the donor substrate interposed therebetween; and
supplying energy by the energy generation device.

10. The method of claim 1, wherein the energy generation device emits light.

11. The method of claim 1, wherein the energy generation device provides a heat source.

12. The method of claim 1, wherein an area of a heat source of the energy generation device is equal to or greater than an area of the donor substrate in a plan view.

13. The method of claim 1, wherein the energy generation device supplies energy toward the first base substrate while moving on the donor substrate.

14. The method of claim 1, wherein the laser device emits laser toward the organic material layer while moving on the donor substrate.

15. The method of claim 1, wherein the display substrate further comprises a hole control layer disposed on the plurality of first electrodes.

16. The method of claim 15, wherein the transferring of the etched organic material layer to the display substrate comprises:
transferring ae light-emitting layer on the hole control layer; and
transferring an electron control layer on the light-emitting layer.

17. The method of claim 1, wherein
the etched organic material layer comprises a hole control layer, a light-emitting layer, and an electron control layer, and
the transferring of the etched organic material layer to the display substrate comprises transferring, all at once, the hole control layer, the light-emitting layer, and the electron control layer, each sequentially stacked, onto each of the plurality of first electrodes.

18. A donor substrate comprising:
a base substrate; and
an etched pattern disposed on the base substrate, including an organic material, and constituting at least a part of a light-emitting element.

19. The donor substrate of claim 18, wherein the base substrate comprises at least one of silicon nitride (Si₃N₄), aluminum nitride (AlN), and silicon carbide (SiC).

20. The donor substrate of claim 18, wherein
the base substrate comprises a light-to-heat conversion layer, and
the base substrate includes at least one of indium-tin oxide (ITO), zinc-tin oxide (ZTO), and fluorinated tin oxide (FTO).

21. The donor substrate of claim 18, wherein
the base substrate comprises a light-to-heat conversion layer, and
the base substrate includes at least one of carbon, silicon, and germanium.

22. The donor substrate of claim 18, wherein
the base substrate comprises a light-to-heat conversion layer, and
the base substrate includes at least one of glass, aluminum oxide (Al₂O₃), and aluminum oxynitride.
